(19) United States
(12) Patent Application Publication
(10) Pub. No.: US 2024/0422960 A1
(43) Pub. Date: Dec. 19, 2024

(54) UNIT CELL, STACK TYPE SEMICONDUCTOR DEVICE INCLUDING THE UNIT CELL AND METHOD OF MANUFACTURING THE STACK TYPE SEMICONDUCTOR DEVICE

(71) Applicant: SK hynix Inc., Gyeonggi-do (KR)

(72) Inventor: Jun Sik KIM, Gyeonggi-do (KR)

(21) Appl. No.: 18/486,160

(22) Filed: Oct. 13, 2023

(30) Foreign Application Priority Data
Jun. 19, 2023 (KR) 10-2023-0078240

(51) Int. Cl. H10B 12/00

(52) U.S. Cl. CPC H10B 12/315; H10B 12/482

(57) ABSTRACT

A unit cell may include an active layer, a separation region and a gate. The active layer may include a first junction region, a second junction region and a channel between the first junction region and the second junction region. The separation region may be formed in the active layer to separate the first junction region and the channel into at least two regions. The gate may be arranged in the separation region.

### CROSS-REFERENCES TO RELATED APPLICATION

The present application claims priority under 35 U.S.C. § 119(a) to Korean application number 10-2023-0078240, filed on Jun. 19, 2023, which is incorporated herein by reference in its entirety.

### BACKGROUND

### 1. Technical Field

Various embodiments generally relate to a semiconductor device and a method of manufacturing the same, more particularly, to a unit cell, a stack type semiconductor device including the unit cell and a method of manufacturing the stack type semiconductor device.

### 2. Related Art

In order to satisfy the high performance and the low cost required by customers, the integration degree of semiconductor devices has increased over time.

Since the integration degree of the semiconductor device is one important factor for determining the cost of the semiconductor, it is desirable to increase the integration degree. In a two-dimensional (2D) or planar semiconductor device, the integration degree is determined by an occupying area of a unit memory cell so that the integration degree is influenced by the technologies for forming a fine pattern.

Because the fine pattern may be formed using expensive equipment, although the integration degree of the 2D semiconductor device may be increased, there exists a limit for the integration degree of a 2D semiconductor device in terms of the above noted customer requirements of high performance and low cost. Thus, a stack type semiconductor memory device including memory cells arranged in a three-dimensional (3D) structure has been considered.

### SUMMARY

According to the disclosed embodiments herein, there is provided a unit cell. The unit cell may include an active layer, a separation region and a gate. The active layer may include a first junction region, a second junction region and a channel between the first junction region and the second junction region. The separation region may be formed in the active layer to separate the first junction region and the channel into at least two regions. The gate may be arranged in the separation region.

According to the disclosed embodiments herein, there is provided a stack type semiconductor device. The stack type semiconductor device may include an active region, a separation region, a plurality of bit lines, a plurality of storage elements and a gate. The active region may include an active layer and an insulating interlayer alternately stacked at least twice to form a plurality of active layers and insulating layers. Each of the active layers may include a first junction region and a second junction region configured to form a channel substantially parallel to a first direction. The separation region may be formed in a plurality of the active layers to separate the channel and the first junction region of each of the active layers into at least two bars. The bit lines may be provided to each of the active layers. The bit lines may be connected with the first junction regions. The storage elements may be provided to each of the active layers. The storage elements may be electrically connected with the second junction regions. The gate may be arranged in the separation region. The gate may be extended in a stack direction of the active layer to have an overlapping portion overlapping with respect to each of the active layers. The separation region may be positioned between the gate and the bit lines. The gate comprises the common gate for the plurality of active layers.

In some embodiments, a length of the separation region between the gate and the bit lines is longer than a distance between the gate and the second junction region.

In other embodiments, the separation region is further positioned between the gate and the second junction region.

In some embodiments, a distance between the storage elements is substantially equal to or longer than the length of the separation region between the gate and the bit lines.

According to the disclosed embodiments herein, there is provided a method of manufacturing a stack type semiconductor device. In the method of manufacturing the stack type semiconductor device, an active layer and an insulation layer may be at least twice stacked to form a stack structure. The active layer may include a first junction region and a second junction region. A separation region may be formed through a selected portion of each of the active layers to separate the first junction region into at least two bars. Bit lines may make contact with the first junction regions separated into the bars corresponding to each of the active layers. Storage elements may be connected to each of the second junction regions corresponding to each of the active layers. A gate may be formed in the separation region to have an overlapped region with each of the active layers.

For example, the active layers and the insulation layer in the active region may be etched to form a separation hole. And then, the separation hole may be filled with a dielectric material, thereby forming the separation region.

According to the disclosed embodiments herein, there is provided a unit cell for a three-dimensional semiconductor device. The unit cell may include an active layer, a separation region and a gate. The active layer may include a first junction region, a second junction region and a channel between the first junction region and the second junction region. The separation region may be formed in the active layer to separate the first junction region and the channel into at least two regions. The gate may be arranged in the separation region. The gate may be vertically extended beyond the separation region for connection to other active layers above the active layer.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1A is a plan view illustrating a unit cell in accordance with various embodiments of the present disclosure;

FIG. 1B is a perspective view illustrating a unit cell in accordance with other embodiments of the present disclosure;

FIG. 2A is a plan view illustrating a unit cell in accordance with other embodiments of the present disclosure;

FIG. 2B is a perspective view illustrating a unit cell in accordance with various embodiments of the present disclosure;

FIGS. 3A and 3B are perspective views illustrating a stack type semiconductor device in accordance with other embodiments of the present disclosure;

FIGS. 4A to 15A are plan views illustrating a method of manufacturing a stack type semiconductor device in accordance with various embodiments of the present disclosure;

FIGS. 4B to 15B are cross-sectional views taken along a line b-b′ in FIGS. 4A to 15A;

FIGS. 7C to 15C are plan views illustrating a method of manufacturing a stack type semiconductor device in accordance with various embodiments of the present disclosure; and

FIGS. 7D to 15D are cross-sectional views taken along a line c-c′ in FIGS. 4C to 15C.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are within the scope of the present disclosure. Thus, the described embodiments should not be construed as being limited to the particular configurations and shapes illustrated herein but deviations in configurations and shapes are included in the scope of the present disclosure.

The present disclosure is described herein with reference to cross-section and/or plan illustrations of the embodiments shown herein. However, the described embodiments of the present disclosure should not be construed as limiting the inventive concept. Although a few embodiments of the present disclosure will be shown and described, it will be appreciated by those of ordinary skill in the art that changes may be made in these embodiments without departing from the scope of the present disclosure.

As noted above, a stack type semiconductor memory device including memory cells arranged in a three-dimensional (3D) structure has been considered as the integration degree of semiconductor devices has increased. However, because the memory cells of the stack type semiconductor memory device are stacked in the 3D structure, elements in the stack type semiconductor memory device may not have desired electrical characteristics. The present disclosure arises in this context.

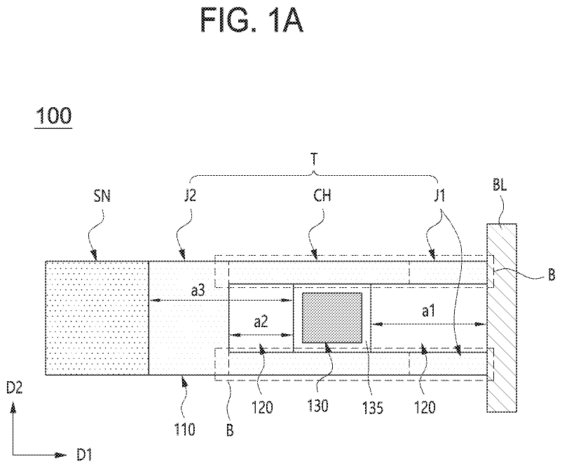

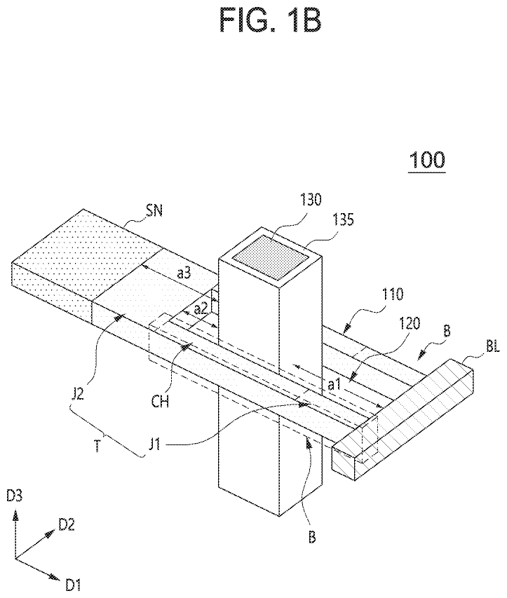

FIG. 1A is a plan view illustrating a unit cell in accordance with various embodiments of the present disclosure and FIG. 1B is a perspective view illustrating a unit cell in accordance with various embodiments of the present disclosure.

Referring to FIGS. 1A and 1B, a unit cell 100 may include a switching element T, a bit line BL and a storage node SN. The storage node SN may be a part of a storage element.

The switching element T may include an active layer 110 and a gate 130. For example, the switching element T may be a transistor.

In some embodiments, the active layer 110 may include a semiconductor material. For example, the active layer 110 may include at least one or more of polysilicon, single crystalline silicon, germanium and silicon-germanium. The active layer 110 may include a first conductive type impurity having a low concentration.

The active layer 110 may have a long axis extended in a first direction D1 and a short axis extended in a second direction D2. The first direction D1 and the second direction D2 may be substantially perpendicular to each other. Further, a third direction D3 may be substantially perpendicular to the first direction D1 and the second direction D2. The third direction D3 may be substantially perpendicular to a surface of the active layer 110, for example, a stack direction.

The active layer 110 may include a first junction region J1 and a second junction region J2. The first junction region J1 may be positioned at one side of the active layer 110. The second junction region J2 may be positioned at the other side of the active layer 110. A channel CH may be formed at the active layer 110 between the first junction region J1 and the second junction region J2. For example, positions of the first junction region J1 and the second junction region J2 may provide the channel CH with a direction substantially parallel to the first direction D1.

The first junction region J1 and the second junction region J2 may correspond to a drain and a source of the transistor, respectively. The first junction region J1 and the second junction region J2 may include a second conductive type impurity opposite to the first conductive type impurity. For example, when the active layer 110 may include p type impurities, the first junction region J1 and the second junction region J2 may include n type impurities having a high concentration such as for example arsenic (As), phosphorus (P), etc. In some embodiments, the low concentration may correspond to a general concentration of an active layer (e.g., in a channel layer) in a semiconductor device. The high concentration may correspond to a general concentration of a drain and a source of a semiconductor device. The low concentration and the high concentration may be changed in accordance with characteristics of the semiconductor device.

The active layer 110 may include a separation region 120. The separation region 120 may separate the channel CH and the first junction region J1 of the active layer 110 into at least two bars B. For example, a long axis of the separation region 120 (i.e., an extending length of the separation region 120 along the first direction D1) may be shorter than the long axis of the active layer 110 (i.e., an extending length of the active layer 110 along the first direction D1). A short axis of the separation region 120 (i.e., an extending length of the separation region 120 along the second direction D2) may be shorter than the short axis of the active layer 110 (i.e., an extending length of the active layer 110 along the second direction D2). One end of the separation region 120 may face the second junction region J2.

In other embodiments, the separation region 120 may include an insulation material or a space filled with air.

Each of the bars B separated by the separation region 120 may include a part of the channel CH and a part of the first junction region J1. Each of the bars B may have substantially the same size, but are not limited thereto.

The gate 130 may be positioned between the first junction region J1 and the second junction region J2. For example, the gate 130 may be positioned in the separation region 120. The gate 130 may be extended in the third direction D3. For example, the gate 130 may include a vertical gate, a vertical pillar gate, a vertical pillar word line, etc., vertically extended with respect to a surface of the active layer 110.

In various embodiments, the gate 130 may include at least one or more of a silicon-base material, a metal-based material and a combination thereof. The gate 130 may include for example at least one or more of silicon, metal, metal nitride, metal silicide and a combination thereof. Alternatively, the gate 130 may include for example at least one or more of polysilicon, titanium nitride, tungsten and a combination thereof. The gate 130 may include at least one or both of polysilicon doped with n type impurities and titanium nitride. The gate 130 may include a stack layer having a titanium nitride layer and a tungsten layer. Further, the gate 130 may include a conductive material having a low work function of for example no more than about 4.5 eV to decrease a threshold voltage of the transistor. A gate insulation layer 135 may be formed on the gate 130. The gate insulation layer 135 may insulate the gate 130 from the active layer 110. Hereinafter, the gate 130 may be a structure including the gate insulation layer 135.

As shown in FIGS. 1A and 1B, a length of the separation region 120 between the gate 130 and the bit line BL may correspond to a first length a1 or a first distance. A length of the separation region 120 between the gate 130 and the second junction region J2 may correspond to a second length a2 or a second distance. Further, the gate 130 may be spaced apart from the storage node SN or the storage element by a third length a3 or a third distance.

The first length a1 may be substantially equal to or different from the second length a2. The first length al may be longer or shorter than the second length a2.

The third length a3 may be substantially equal to or longer than the first length a1. For example, when the third length a3 may be longer than the first length a1, a gate induced drain leakage (GIDL) caused by a row hammering may be decreased. When the gate 130 may be operated as a pass gate, charges in the storage node SN may be trapped on a surface of the gate 130. After that, when the gate 130 is not turned on, that is, no voltage is applied to the gate 130, the charges trapped on the surface of the gate 130 may be electrically floated and flow toward other electrical components of the memory cell 100, for example, the bit line BL located closer the storage node SN. In an embodiment, as the storage node SN is spaced apart from the gate 130 by the third length a3 longer than the first length a1, a path through which the charges leaking from the storage node SN are transmitted to the gate 130 becomes longer, when the gate 130 operates as the pass gate. Thus, an amount of the charges trapped by the gate 130 operating as the pass gate may be reduced.

Further, since the separation region 120 is interposed between the gate 130 and the bit line BL, the flow of the charges trapped on the gate 130 toward to the bit line BL receiving a voltage may be blocked by the separation region 120, when the gate is not turned on. Thus, a charge loss of the storage node SN may be prevented. A leakage current caused by row hammering and the GIDL may also be prevented.

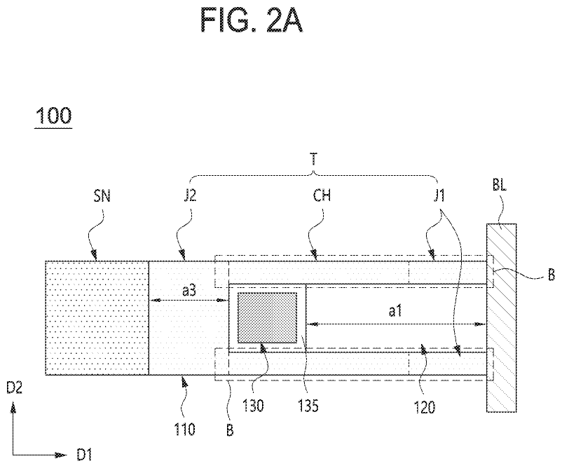

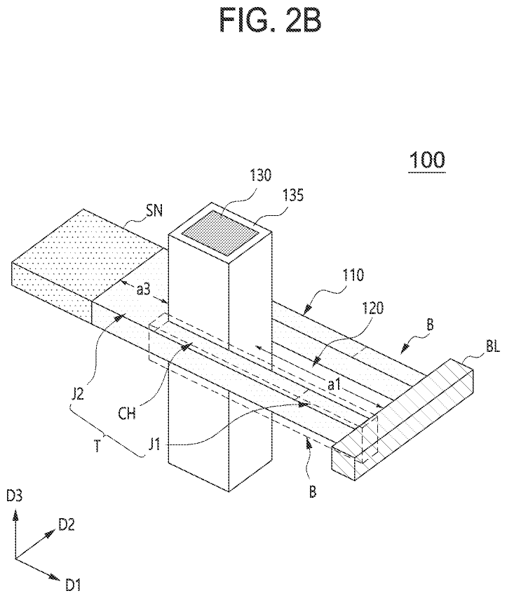

As shown in FIGS. 2A and 2B, the gate 130 may face the second junction region J2 without a gap. Particularly, only the gate insulation layer 135 may be positioned between the gate 130 and the second junction region J2. However, a gap between the gate 130 and the storage node SN, i.e., the third length a3 may be substantially equal to or longer than the first length a1.

As mentioned above, the bit line BL may be connected to the first junction region J1 separated into the bars B. The bit line BL may be extended in the second direction D2. For example, the bit line BL may be connected to the at least two bar B shaped first junction regions J1 and the separation region 120 between the first junction regions J1.

The storage element may include the storage node SN, a storage electrode, a dielectric layer and a plate electrode. The storage node SN may be electrically connected with the second junction region J2. The storage electrode may make contact with the storage node SN.

According to various embodiments, the separation region 120 may be formed in the active layer 110 to control the gap between the gate 130 and the bit line BL. The separation region 120 between the gate 130 and the bit line BL may greatly decrease a parasitic capacitance between the gate 130 and the bit line BL.

Further, the separation region 120 may also be arranged between the gate 130 and the second junction region J2 to decrease the parasitic capacitance. The separation region 120 may form a relatively large gap between the gate 130 and the storage node SN to reduce the GIDL. The separation region 120 may decrease the parasitic capacitances between the storage electrode and the bit line BL, between the plate electrode of the storage node and the bit line BL and between the plate electrode of the storage node and the gate 130.

Furthermore, the vertical pillar-shaped gate 130 may reduce a channel inversion speed as compared to a dual gate structure. Thus, a threshold voltage characteristic of the transistor may be controlled.

The gate 130 may be formed using various conductive materials. As a result, the leakage current in the unit cell 100 caused by various reasons may also be decreased. The active layer 110 in FIGS. 1A, 1B, 2A and 2B may be vertically stacked to form a stack type semiconductor device.

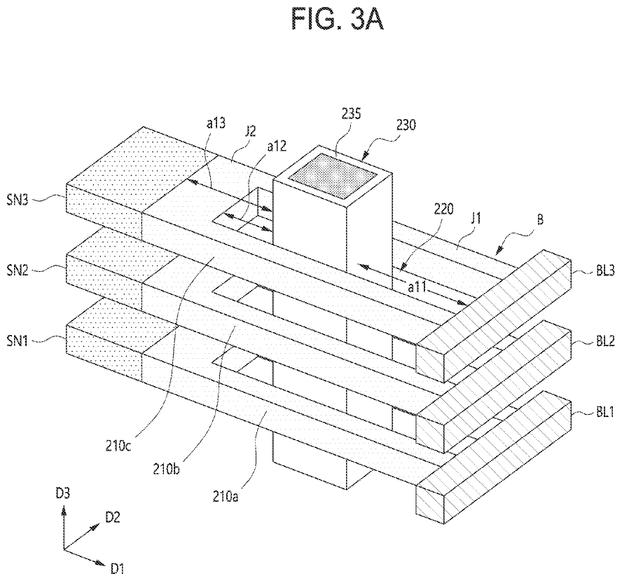

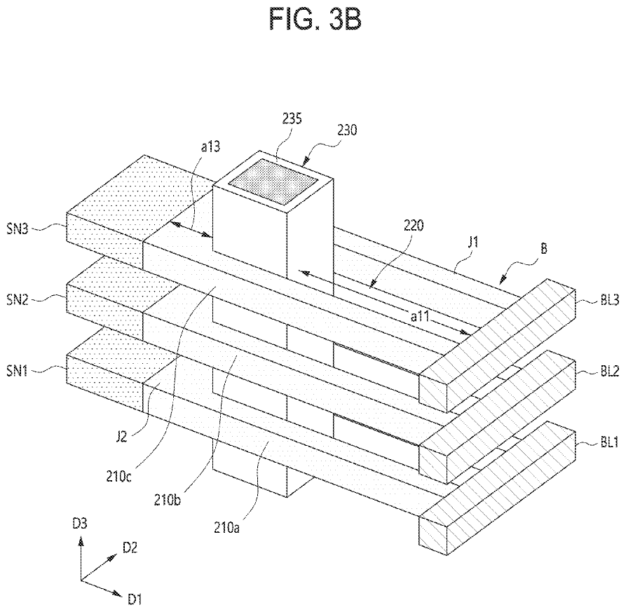

FIGS. 3A and 3B are perspective views illustrating a stack type semiconductor device in accordance with other embodiments of the present disclosure. FIGS. 3A and 3B may show three active layers stacked in one gate.

Referring to FIG. 3A, a stack type semiconductor device 200 of these embodiments may include vertically stacked active layers 210a, 210b and 210c, a separation region 220, a gate 230, a plurality of bit lines BL1, BL2 and BL3 and a plurality of storage nodes SN1, SN2 and SN3.

The active layers 210a, 210b and 210c may be stacked above each other and extend along the third direction D3. The active layers 210a, 210b and 210c may be spaced apart from each other by a gap so that the active layers 210a, 210b and 210c may be electrically isolated from each other. An insulation layer (not shown) may be interposed between the active layers 210a, 210b and 210c. Each of the active layers 210a, 210b and 210c may include the first junction region J1, the channel CH and the second junction region J2 described in the descriptions of FIGS. 1A to 2B.

The separation region 220 may be positioned in the active layers 210a, 210b and 210c. The separation region 220 may separate the channel CH and the first junction region J1 of each of the active layers 210a, 210b and 210c into at least two bars B. The separation region 220 of the active layers 210a, 210b and 210c may be connected with each other. For example, the separation region 120 may have a plug structure formed through the active layers 210a, 210b and 210c. Further, the separation region 220 may include an insulation material.

The gate 230 may be positioned in the separation region 220. The gate 230 may be extended in the separation region 220 of the active layers 210a, 210b and 210c along the third direction D3. Thus, the gate 230 may have a pillar structure so that the gate 230 may be operated as a common gate of the active layers 210a, 210b and 210c. A gate insulation layer 235 may be formed on a sidewall of the gate 230.

The bit lines BL1, BL2 and BL3 may be stacked over each other in the third direction D3 to correspond to the active layers 210a, 210b and 210c. Each of the bit lines BL1, BL2 and BL3 may make contact with the first junction regions J1 having the bar B shape of the active layers 210a, 210b and 210c. The bit lines BL1, BL2 and BL3 may be electrically isolated from each other by an insulation layer similarly to the active layers 210a, 210b and 210c. The bit lines BL1, BL2 and BL3 may extend in the second direction D2.

The storage nodes SN1, SN2 and SN3 may be electrically connected with the second junction regions J2 of the active layers 210a, 210b and 210c. The storage nodes SN1, SN2 and SN3 may be parts of the storage elements.

In some embodiments, the gate 230 may be spaced apart from the first junction region J1 by a first distance a11, i.e., a length of the separation region 220 between the bit lines BL1, BL2 and BL3. The gate 230 may be spaced apart from the second junction region J2 by a second distance a12. As shown in FIG. 3B, the gate 230 may face the second junction region J2 around the gate insulation layer 235.

The gate 230 may be spaced apart from the storage element (i.e., the storage nodes SN1, SN2 and SN3) by a third distance a13. The third distance a13 may be longer than the first distance a11 to reduce the GIDL.

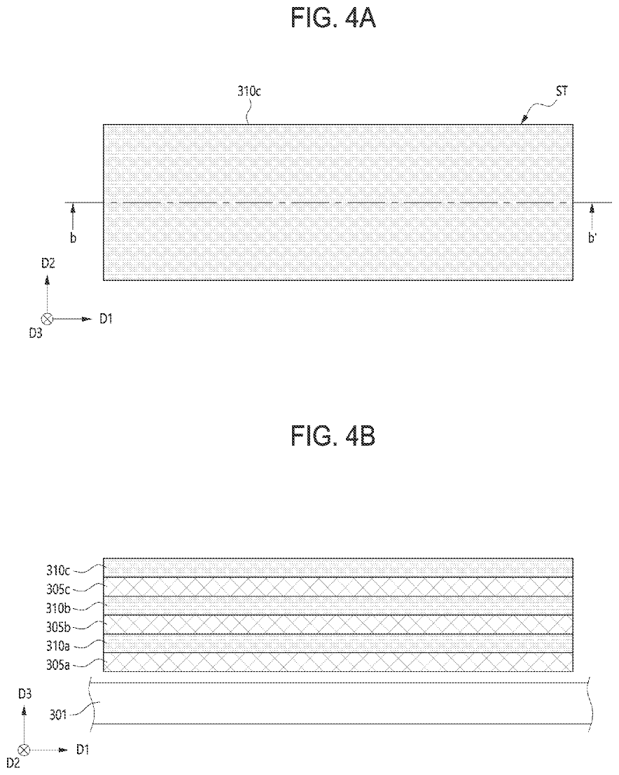

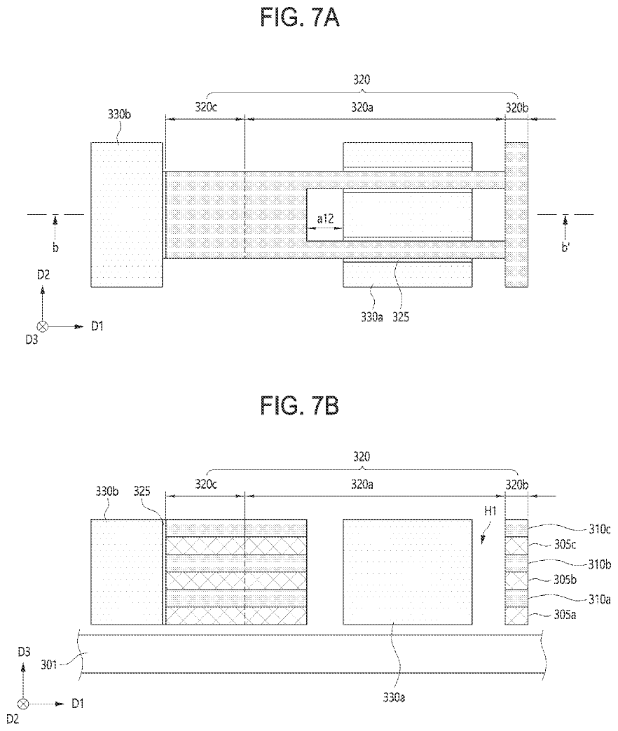

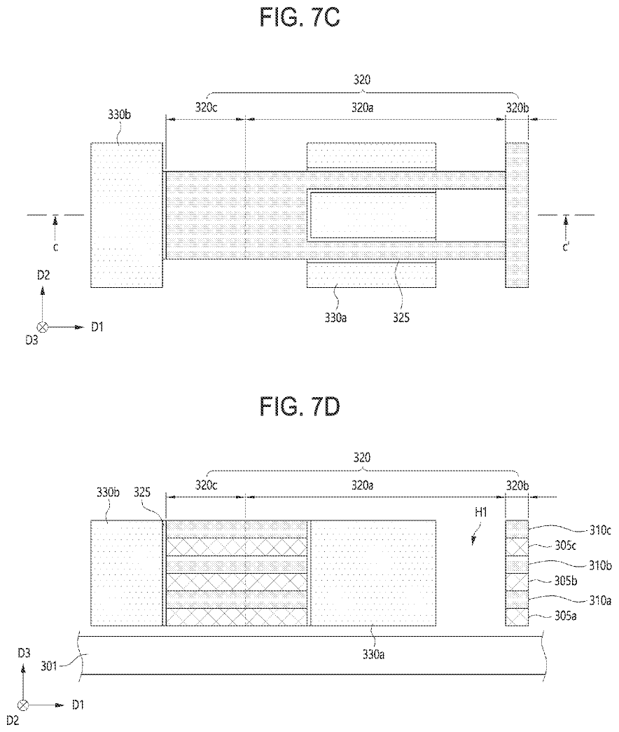

FIGS. 4A to 15A are plan views illustrating a method of manufacturing a stack type semiconductor device in accordance with various embodiments of the present disclosure. FIGS. 4B to 15B are cross-sectional views taken along a line b-b′ in FIGS. 4A to 15A, FIGS. 7C to 15C are plan views illustrating a method of manufacturing a stack type semiconductor device in accordance with various embodiments of the present disclosure. FIGS. 7D to 15D are cross-sectional views taken along a line c-c′ in FIGS. 4C to 15C.

Referring to FIGS. 4A and 4B, first layers 305a, 305b and 305c and second layers 310a, 310b and 310c may be stacked at least twice. The first layers 305a, 305b and 305c and the second layers 310a, 310b and 310c may be stacked on a lower layer 301. The lower layer 301 may include a circuit layer, a substrate with a circuit layer, an interposer with a circuit layer, a semiconductor device including at least one of a circuit layer and memory cells, etc.

The first layers 305a, 305b and 305c may include a sacrificial layer. The second layers 310a, 310b and 310c may include a semiconductor layer used as an active layer. The first layers 305a, 305b and 305c and the second layers 310a, 310b and 310c may have different etching selectivities.

For example, when the second layers 310a, 310b and 310c as the active layer may include silicon, the first layers 305a, 305b and 305c may include silicon germanium (SiGe).

Alternatively, when the second layers 310a, 310b and 310c may include silicon germanium, the first layers 305a, 305b and 305c may include silicon or materials having an etching selectivity with respect to the silicon germanium.

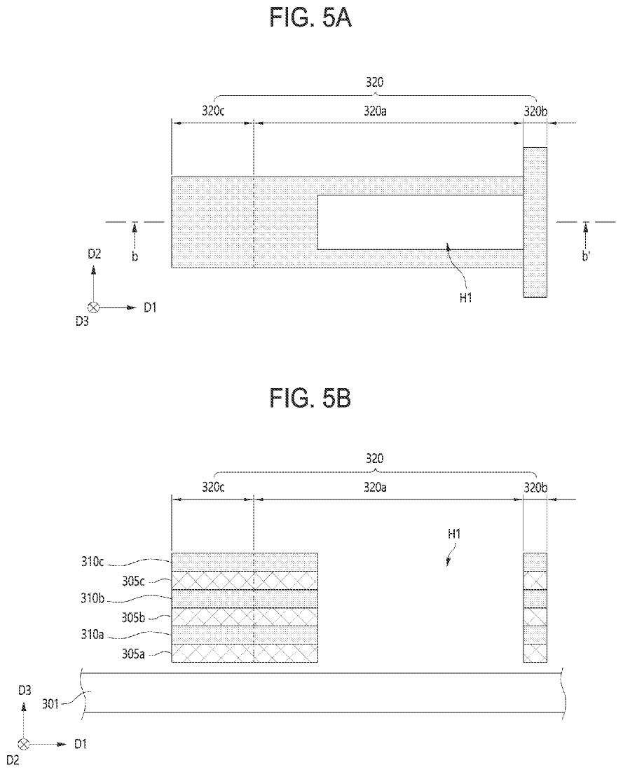

Referring to FIGS. 5A and 5B, the first layers 305a, 305b and 305c and the second layers 310a, 310b and 310c may be patterned to form a stack structure 320.

For example, the stack structure 320 may include a switching element region 320a, a bit line region 320b and a storage region 320c. A first junction region, a second junction region and a channel of a switching transistor may be formed in the switching element region 320a. The switching element region 320a may have a long axis substantially parallel to a first direction D1 and a short axis substantially parallel to a second direction D2. The switching element region 320a may include a separation hole H1 formed through the switching element region 320a.

The bit line region 320b may be positioned at a first end of the switching element region 320a. A sidewall of the bit line region 320b may make contact with the switching element region 320a and may be adjacent the separation hole H1.

The storage region 320c may be positioned at a second end of the switching element region 320a. A first junction formation region may be formed in the switching element region 320a making contact with the bit line region 320c. A second junction formation region may be formed in the switching element region 320a making contact with the storage region 320c.

For example, the separation hole H1 may be formed simultaneously with the stack structure 320. Alternatively, the separation hole H1 may be formed by a process different from a process for forming the stack structure 320.

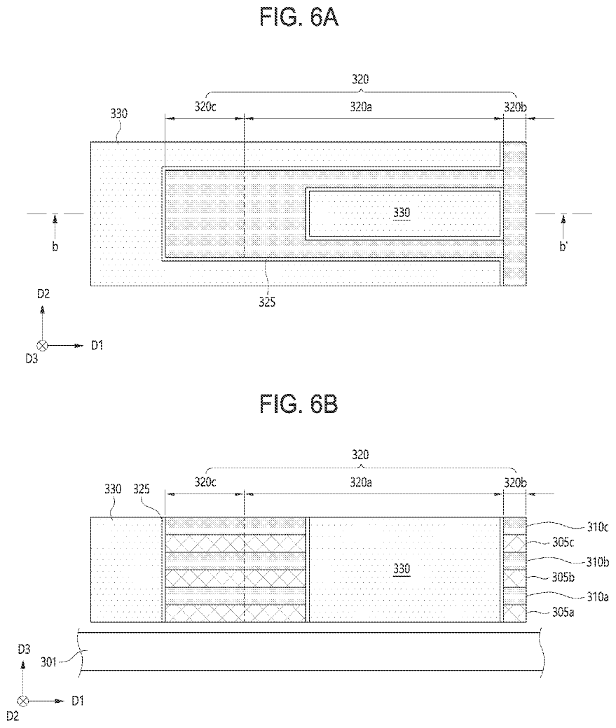

Referring to FIGS. 6A and 6B, a first insulation layer 325 and a sacrificial layer 330 may be formed on a sidewall of the stack structure 320.

In some embodiments, the first insulation layer 325 may be formed on a surface of the stack structure 320. The first insulation layer 325 may be anisotropically etched to retain the first insulation layer 325 on the sidewall of the stack structure 320.

A space outside the stack structure 320 may be filled with the sacrificial layer 330. The sacrificial layer 330 may include a semiconductor material such as for example amorphous silicon, polysilicon, and/or epitaxially grown silicon. The sacrificial layer 330 may be planarized to have an upper surface substantially coplanar with an upper surface of the stack structure 320.

Referring to FIGS. 7A and 7B, the sacrificial layer 330 may be patterned to form a preliminary gate line 330a and a sacrificial plate line 330b, thereby partially exposing the sidewall of the stack structure 320.

In a planar view, the preliminary gate line 330a and the plate region 330b may be extended in the second direction D2. Further, a part of the preliminary gate line 330a may be positioned in the separation hole H1. The sacrificial plate line 330b may be positioned outside the storage region 320c.

For example, the preliminary gate line 330a in the separation hole H1 may be spaced apart from the second junction formation region by a second distance a12.

Alternatively, as shown in FIGS. 7C and 7D, the preliminary gate line 330a in the separation hole H1 may make contact with the second junction formation region around the first insulation layer 325.

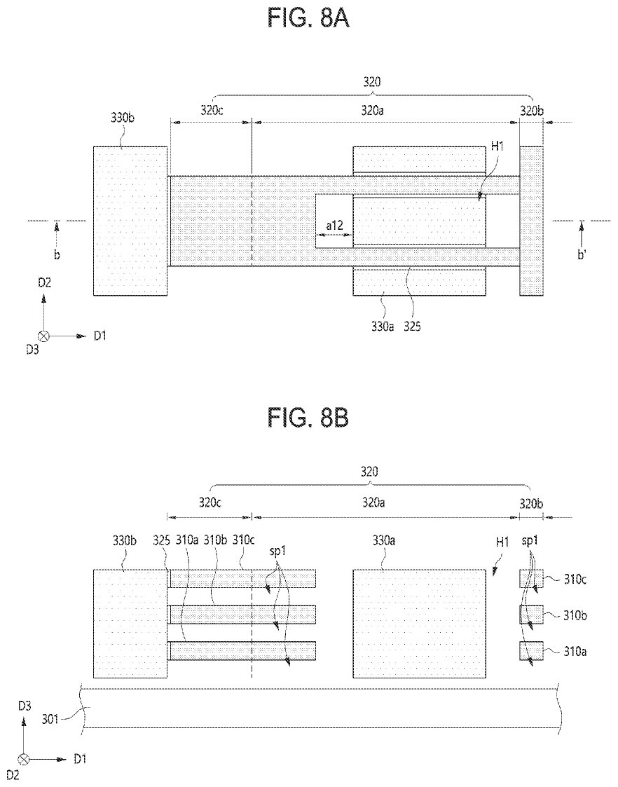

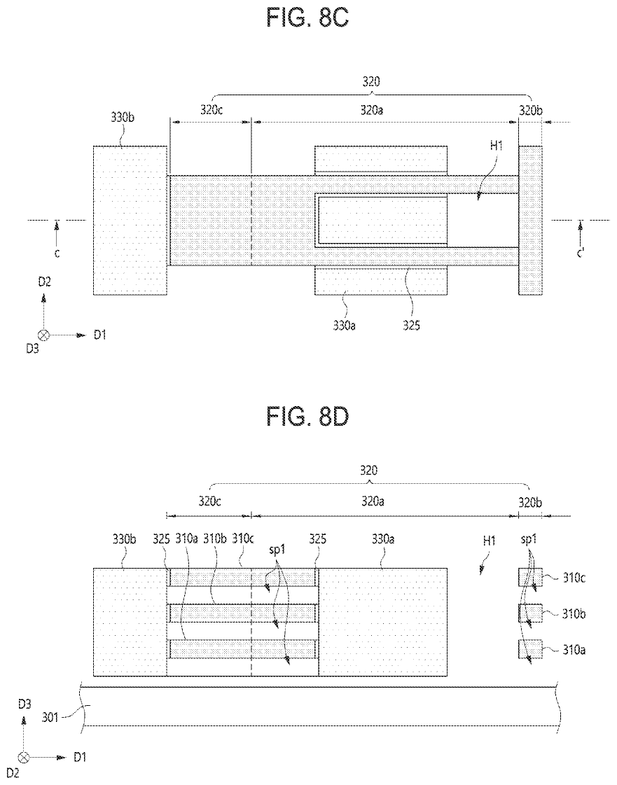

Referring to FIGS. 8A to 8D, the first layers 305a and 305b of the stack structure 320 may be selectively removed to define spaces sp1. For example, an etchant may be provided through the exposed sidewall of the stack structure 320 to selectively remove the first layers 305a, 305b and 305c.

Hereinafter, the selective removal or the selective etch may be performed with at least one of an etching process using a difference between etching selectivities of layers and a process for removing an exposed region using a mask.

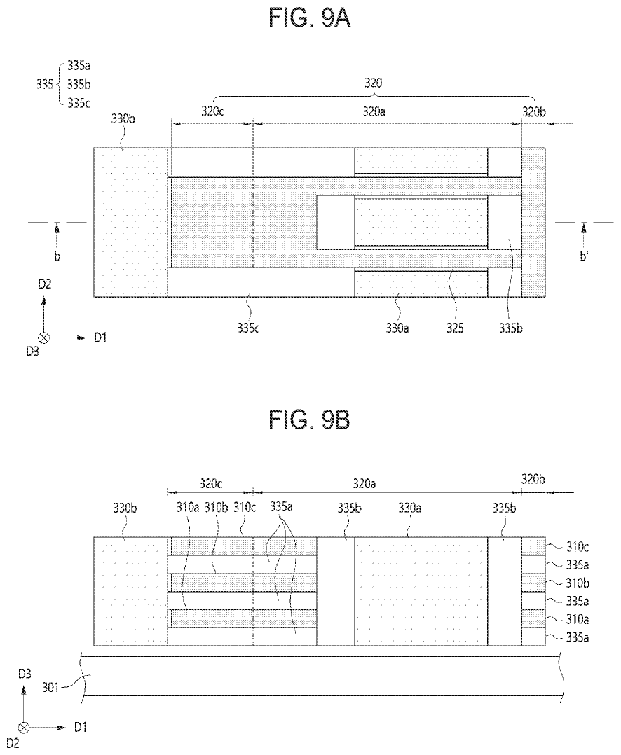

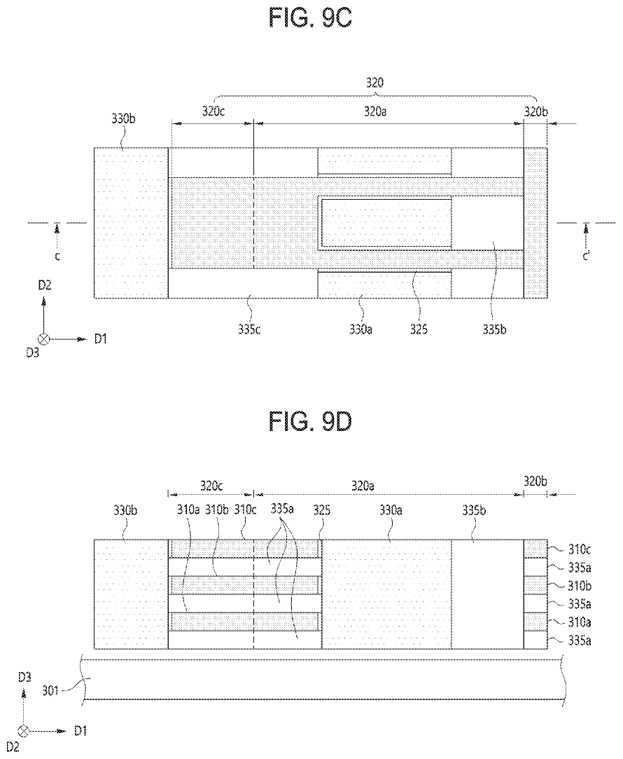

Referring to FIGS. 9A to 9D, a second insulation layer 335 may be formed outside the stack structure 320 to fill the spaces sp1 and the separation hole H1.

The second insulation layer 335 may include a material having gap-filling characteristics and having a low dielectric constant. For example, the second insulation layer 335 may include a spin on dielectric (SOD), but the present disclosure is not limited thereto.

The second insulation layer 335 in the spaces sp1 may electrically insulate the second layers 310a, 310b and 310c of the stack structure 320 from each other. The second insulation layer 335 in the separation hole H1 may electrically isolate the preliminary gate line 330a from the bit line 330b and/or the preliminary gate line 330a from the second junction formation region. The second insulation layer 335 outside the stack structure 320 may be used for a device isolation layer configured to electrically isolate the stack structures 320 from each other. The second insulation layer 335 in the separation hole H1 may correspond to the separation region 120 in FIG. 1.

Alternatively, the formation of the second insulation layer 335 may be omitted. The spaces sp1 and the separation hole H1 may be filled with air. A second insulation layer 335c may be formed outside only the stack structure 320.

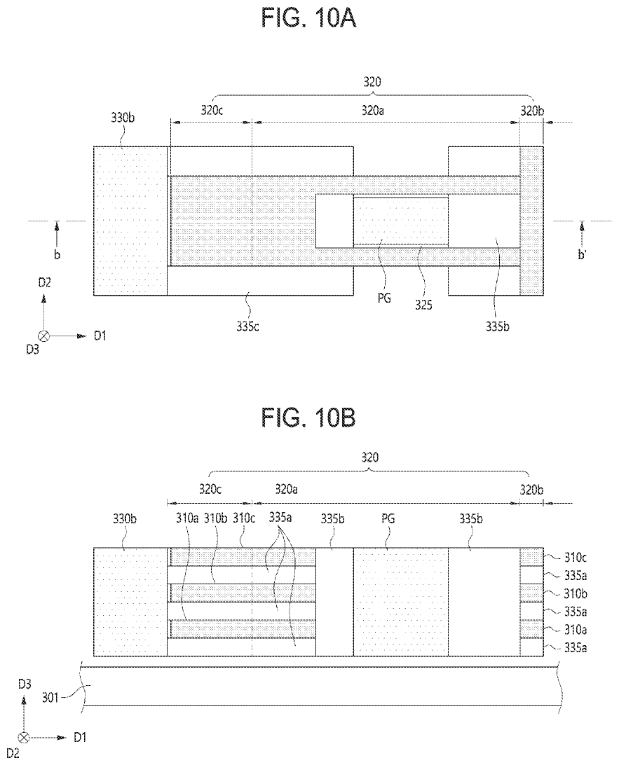

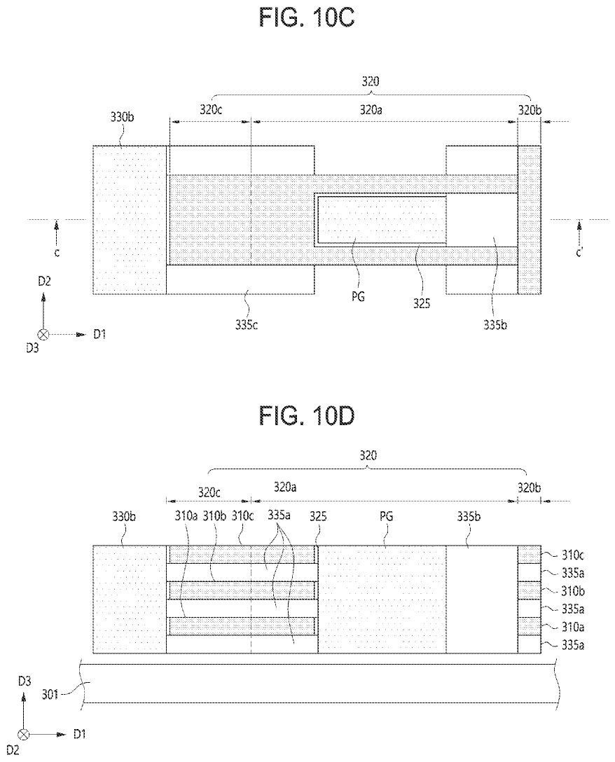

Referring to FIGS. 10A to 10D, the preliminary gate line 330a may be patterned to form a preliminary gate PG in the separation hole H1.

For example, the preliminary gate line 330a outside the separation hole H1 may be removed to form the preliminary gate PG. The preliminary gate PG may be isolated from the second layers 310a, 310b and 310c of the switching element region 320a by the first insulation layer 325. Further, the preliminary gate PG may be isolated from the bit line region 320b and the second junction formation region by the second insulation layer 335b in the separation hole H1.

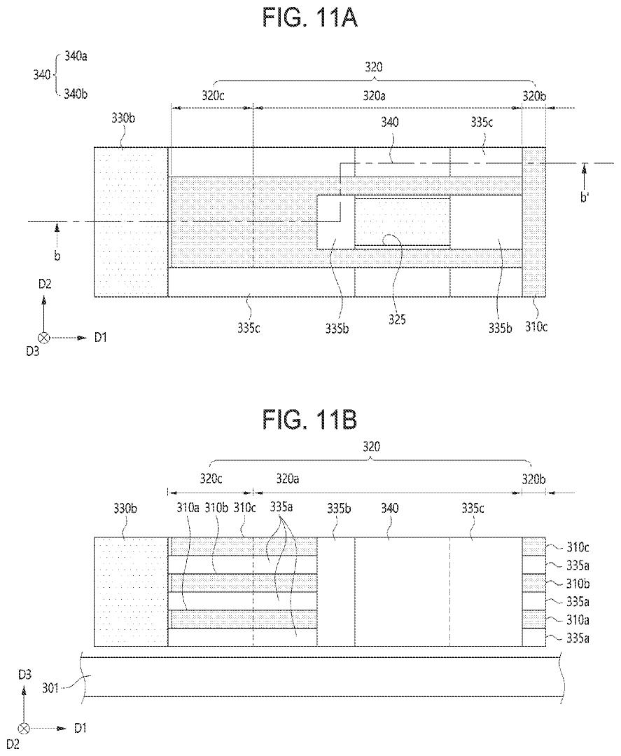

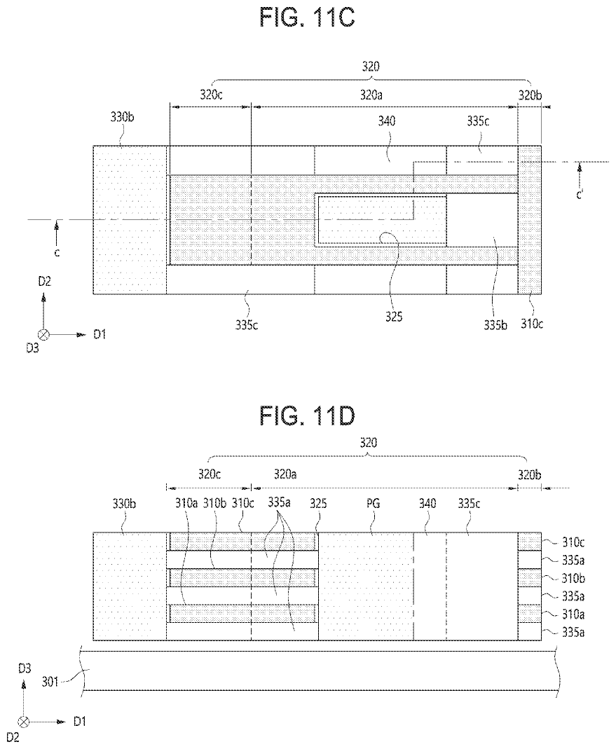

Referring to FIGS. 11A to 11D, a third insulation layer 340 may be formed in a space between the second insulation layers 335c.

The third insulation layer 340 may include a material substantially the same as the material of the second insulation layers 335a, 335b and 335c. The third insulation layer 340 may have a thickness corresponding to a height of the stack structure 320. The third insulation layer 340 may be used for a device isolation layer similarly to the second insulation layer 335c.

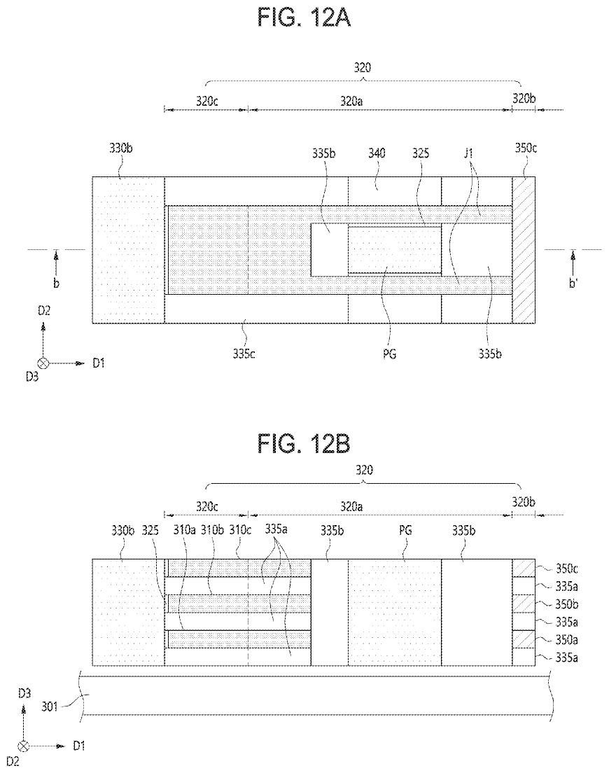

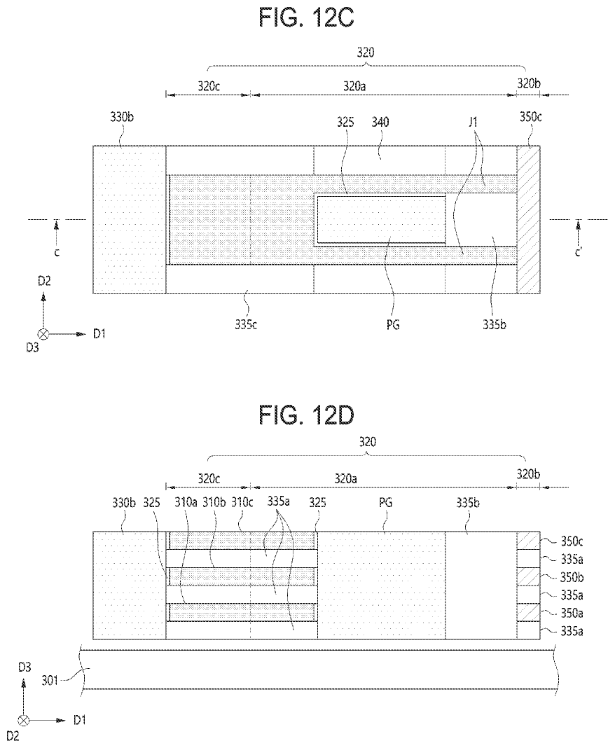

Referring to FIGS. 12A to 12D, a plurality of bit lines 350a, 350b and 350c may be formed in the bit line region 320b. Particularly, the second layers 310a, 310b and 310c of the bit line region 320b may be selectively removed to define spaces between the second insulation layers 335c of the bit line region 320b. The spaces may be filled with a conductive material to form the bit lines 350a, 350b and 350c.

In some embodiments, the bit lines 350a, 350b and 350c may include for example one or more of conductive silicon, metal, metal nitride, metal silicide, a combination thereof, etc. The bit lines 350a, 350b and 350c may include one or more of titanium nitride, tungsten, a combination thereof, etc. The bit lines 350a, 350b and 350c may include at least one of polysilicon doped with n⁺ type impurities and titanium nitride. The bit lines 350a, 350b and 350c may include a stack structure including a titanium nitride layer and/or a tungsten layer. A planar structure of the bit lines 350a, 350b and 350c may be a stripe structure extended in the second direction D2.

In some embodiments, impurities may be implanted into the first layers 305a, 305b and 305c of the switching element region 320a exposed through the spaces, i.e., the first junction formation region between the formation of the spaces and the formation of the bit lines 350a, 350b and 350c to form the first junction region J1. The first junction region J1 may include n type impurities having a high concentration.

Therefore, the first junction regions J1 and the bit lines 350a, 350b and 350c on a same layer or a same level may be connected with each other.

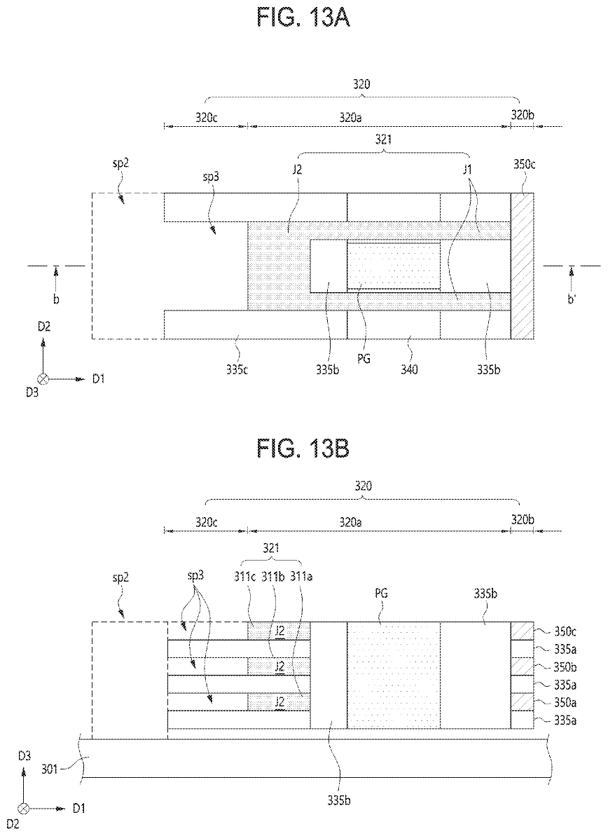

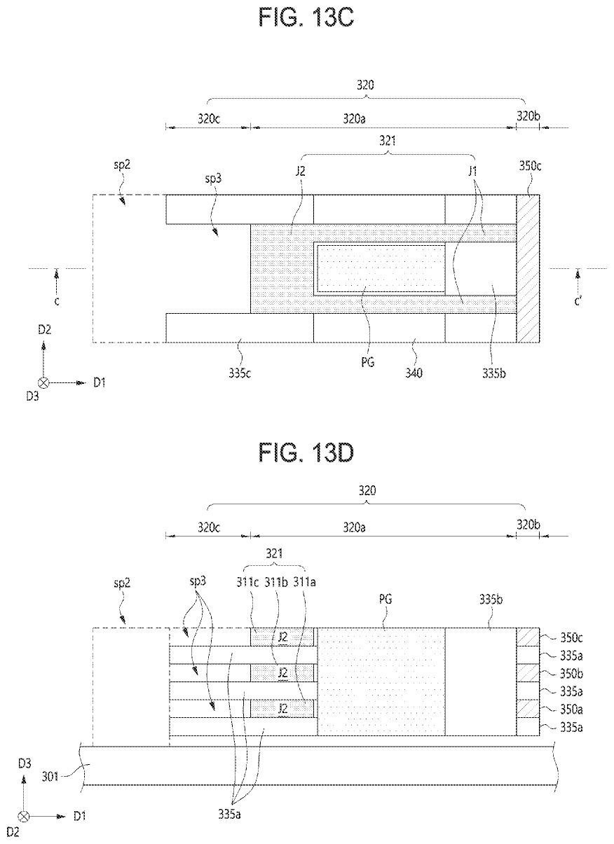

Referring to FIGS. 13A to 13D, n type impurities having a high concentration may be implanted into the second junction formation region to form the second junction region J2.

Particularly, the sacrificial plate line 330b may be selectively removed to form a plate space sp2, thereby exposing a sidewall of the storage region 320c.

An etchant may be provided through the exposed sidewall of the storage region 320c. Thus, the second layers 310a, 310b and 310c of the storage region 320c may be selectively removed to define a storage space sp3 between the second insulation layers 335a of the storage region 320c. Further, the second junction formation region of the switching element region 320a may also be exposed through the storage space sp3.

N type impurities having a high concentration may be implanted into the second junction formation region, i.e., the first layers 305a, 305b and 305c of the exposed switching element region 320a to form the second junction region J2.

Reference numerals 311a, 311b and 311c may indicate an active layer including first and second junction regions and a channel region. A reference numeral 321 may indicate an active region including the stacked active layers 311a, 311b and 311c.

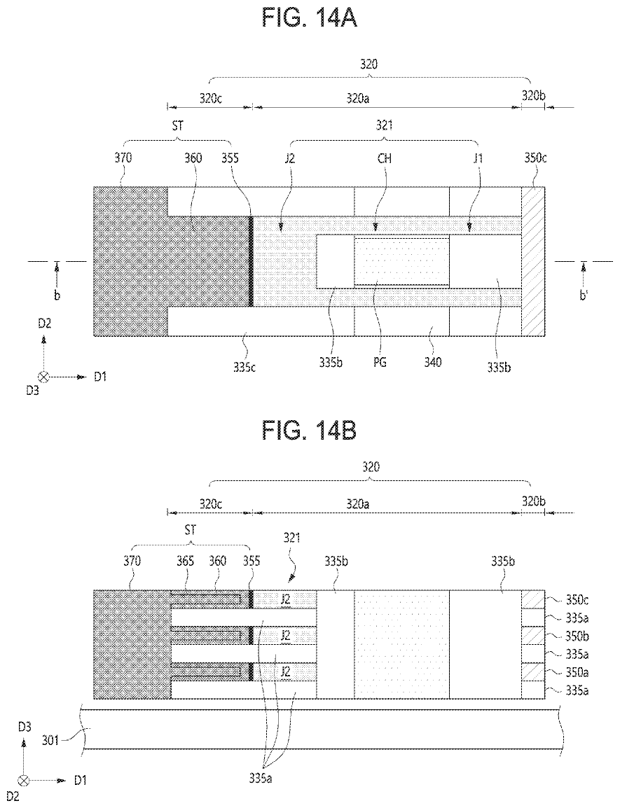

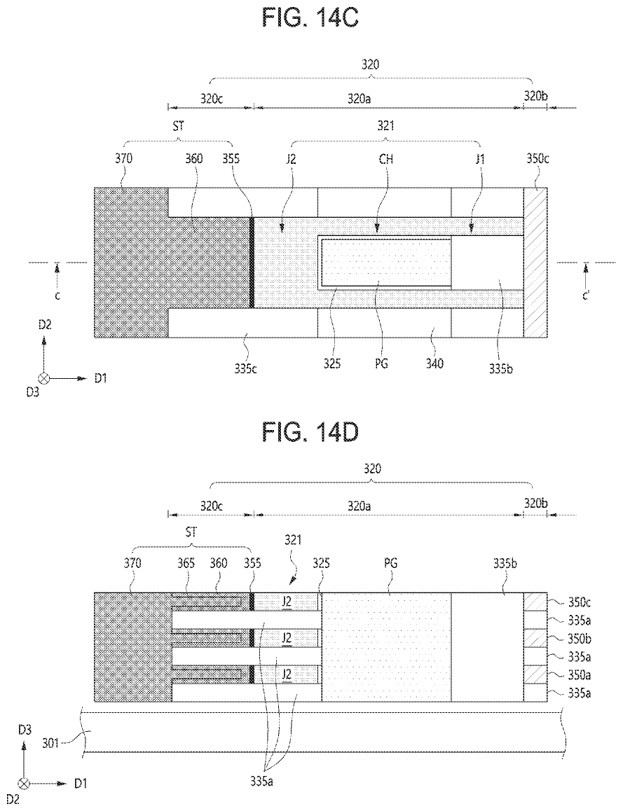

Referring to FIGS. 14A to 14D, a storage element ST may be formed in the storage spaces sp3 and the plate space sp2.

In some embodiments, the storage element ST may include a storage node contact 355, a storage electrode 360, a dielectric layer 365 and a plate electrode 370.

The storage node contact 355 may be formed on the second junction regions J2 exposed through the storage spaces sp3. For example, the storage node contact 355 may include for example at least one or more of a polysilicon layer doped with impurities, a metal silicide layer and a stack layer including a polysilicon layer doped with impurities, and a metal silicide layer.

The storage electrode 360 may be conformally formed on a surface of the storage node contact 355 and inner surfaces of the storage spaces sp3. The storage electrode 360 may be formed by forming a conductive layer and etching-back the conductive layer to expose a sidewall of the second insulation layer 335a. The storage electrode 360 may have a cylindrical shape.

The storage electrode 360 may include for example one or more of a metal layer, a noble metal layer, a metal nitride layer, a conductive metal oxide layer, a conductive noble metal oxide layer, a metal carbon layer, a metal silicide layer, a combination thereof, etc. For example, the storage electrode 360 may include one or more of Ti, TiN, Ta, TaN, W, WN, Ru, RuO₂, Ir, IrO₂, Pt, Mo, MoO, TiN/W, WN/W, etc.

The dielectric layer 365 may be formed on a surface of the storage electrode 360. The dielectric layer 365 may correspond to a capacitor dielectric layer or a memory layer. The dielectric layer 365 may include for example one or more of a silicon oxide layer, a silicon nitride layer, a high-k material, a combination thereof, etc. The high-k material may have a dielectric constant higher than that of a silicon oxide layer. For example, the dielectric constant of the material may be for example no less than about 20. The high-k material may include one or more of HfO₂, ZrO₂, Al₂O₃, La₂O₃, TiO₂, Ta₂O₅, Nb₂O₅, SrTiO₃, etc. Alternatively, the dielectric layer 360 may include a complex layer including at least two layers of the above-mentioned materials.

The dielectric layer 365 may include a Zr-base oxide layer. The dielectric layer 365 may include a stack structure including a ZrO₂ layer. The dielectric layer 365 may include a ZA(ZrO₂/Al₂O₃) structure and/or a ZAZ(ZrO₂/Al₂O₃/ZrO₂) structure. The ZA structure may include the Al₂O₃ layer stacked on the ZrO₂. The ZAZ structure may include the ZrO₂ layer, the Al₂O₃ layer and the ZrO₂ layer sequentially stacked. The ZA structure and the ZAZ structure may correspond to a ZrO₂-base layer. Alternatively, the dielectric layer 365 may have a stack structure including an HfO₂ layer. The dielectric layer 365 may have an HA(HfO₂/Al₂O₃) structure and/or an HAH(HfO₂/Al₂O₃/HfO₂). The HA structure may include the Al₂O₃ layer stacked on the HfO₂ layer. The HAH structure may include the HfO₂ layer, the Al₂O₃ layer and the HfO₂ layer sequentially stacked. The HA structure and the HAH structure may be an HfO₂-base layer. In the ZA structure, the ZAZ structure, the HA structure and the HAH structure, the Al₂O₃ layer may have band gap energy higher than band gap energy of the ZrO₂ layer and the HfO₂ layer. The Al₂O₃ layer may have a dielectric constant lower than dielectric constants of the ZrO₂ layer and the HfO₂ layer. Thus, the dielectric layer 365 may have a stack structure including the high-k material and the high band gap material. The band gap energy of the high band gap material may be higher than the band gap energy of the high-k material. The dielectric layer 365 may include a SiO₂ layer as another high band gap material besides the Al₂O₃ layer. The dielectric layer 365 may include the high band gap material to suppress the leakage current. The high band gap material may have a thickness thinner than a thickness of the high-k material. Alternatively, the dielectric layer 365 may have a laminated structure including the high-k material and the high band gap material alternately stacked. For example, the dielectric layer 365 may include for example one or more of a ZAZA(ZrO₂/Al₂O₃/ZrO₂/Al₂O₃) structure, a ZAZAZ(ZrO₂/Al₂O₃/ZrO₂/Al₂O₃/ZrO₂) structure, a HAHA(HfO₂/Al₂O₃/HfO₂/Al₂O₃) structure or a HAHAH(HfO₂/Al₂O₃/HfO₂/Al₂O₃/HfO₂) structure. In the laminated structure, the Al₂O₃ layer may have a thickness thinner than thicknesses of the ZrO₂ layer and the HfO₂ layer.

Further, the dielectric layer 365 may have a stack dielectric structure including a ZrO₂ layer, an HfO₂ layer and an Al₂O₃ layer, a laminated structure or a mixed structure thereof.

The plate electrode 370 may be filled in the storage space sp3 and the plate space sp2 on the dielectric layer 365.

The plate electrode 370 may include a conductive material substantially the same as or different from the material of the storage electrode 360. The plate electrode 370 may include a combination of a metal-base material and a silicon-base material.

An interface control layer for improving the leak current may be formed between the storage electrode 360 and the dielectric layer 365 and/or the dielectric layer 365 and the plate electrode 370. The interface control layer may include for example one or more of TiO₂, Ta₂O₅, Nb₂O₅, etc.

The storage electrode 360 may be positioned in the storage spaces sp3 by the etch-back process. Thus, the stacked storage electrodes 360 may be separated from each other. In various embodiments, the storage node contact 355 and the storage electrode 460 in the storage space sp3 may correspond to the storage node SN in FIGS. 1A to 3B.

The plate electrode 370 may cover the stacked storage electrodes 360. That is, the stacked storage electrodes 360 may be separated from each other. The plate electrode 370 may be extended in the third direction D3 without a disconnection so that the plate electrode 370 may be overlapped with all of the stacked storage electrodes 360.

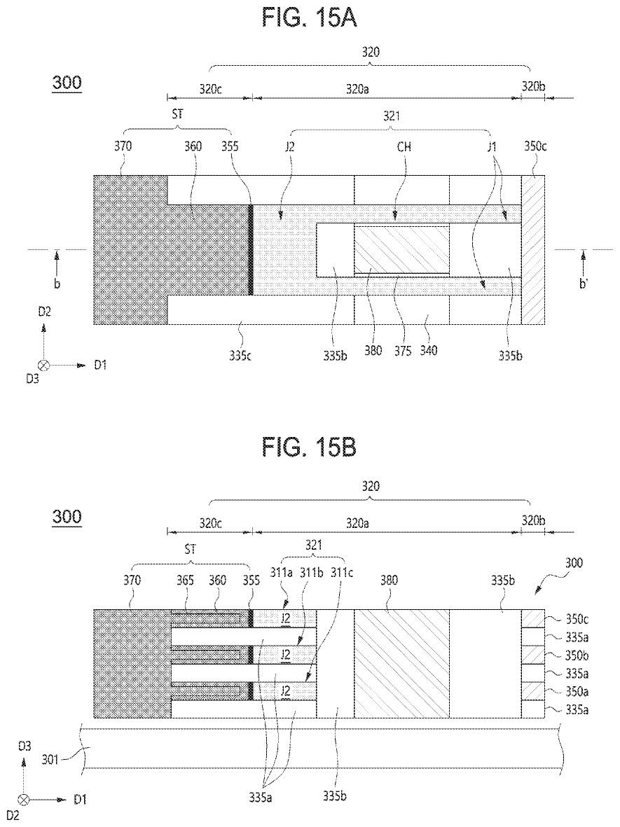

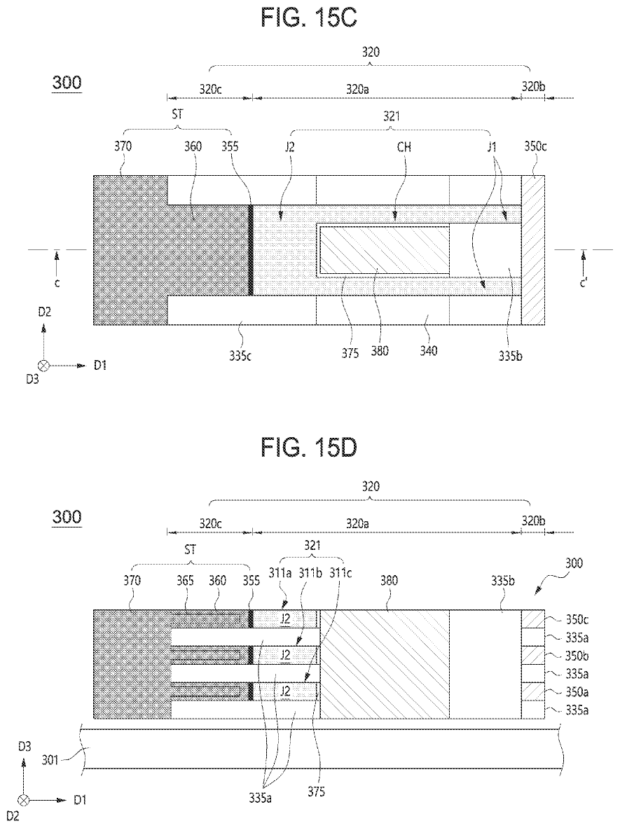

Referring to FIGS. 15A to 15D, a gate 380 may be formed in a region where the preliminary gate PG was positioned to complete the stack type semiconductor device 300.

Particularly, the preliminary gate PG may be selectively removed to form a gate space in the separation hole H1. Further, the first insulation layer 325 between the active layers 311a, 311b and 311c and the preliminary gate PG may also be removed together with the preliminary gate PG.

A gate insulation layer 375 may be conformally formed on an inner side surface of the gate space. The gate space with the gate insulation layer 375 may be filled with a gate conductive layer to form the gate 380 having a vertical pillar shape. The gate 380 may be partially overlapped with the stacked active layers 311a, 311b and 311c so that the gate 380 may be operated as a common gate of the switching elements at the active layers 311a, 311b and 311c of the active region 321. The gate 380 may include for example one or more of a TiN/W layer, a polysilicon including conductive impurities, etc. Alternatively, the gate 380 may include a conductive layer having a low work function or a high work function considering the threshold voltage characteristics of the switching transistor.

For example, a portion of the gate 380 adjacent to the first junction region J1 and/or the second junction region J2 may include a conductive layer having a low work function. A portion of the gate 380 corresponding to the channel CH may include a conductive layer having a high work function.

According to various embodiments, the separation region may be formed between the gate and the bit line to define the distance between the gate and the storage node. Thus, the separation region including the insulation material may be interposed between the gate and the bit line to reduce the parasitic capacitance. Further, because the size of the separation region may be determined in accordance with the distance between the gate and the storage node, the GIDL may be additionally decreased. Furthermore, the switching element may be operated in a single gate type to control the threshold voltage.

The above described embodiments of the present disclosure are intended to illustrate and not to limit the present disclosure. Various alternatives and equivalents are possible. The disclosure is not limited by the embodiments described herein. Nor is this disclosure limited to any specific type of semiconductor device. Other additions, subtractions, and/or modifications are within the scope of the present disclosure. Furthermore, the embodiments may be combined to form additional embodiments.

1. A unit cell comprising:
an active layer including a first junction region, a second junction region and a channel between the first junction region and the second junction region;
a separation region formed in the active layer to separate the first junction region and the channel into at least two portions; and
a gate arranged in the separation region.

2. The unit cell of claim 1, wherein the separation region comprises an insulation material.

3. The unit cell of claim 1, further comprising a bit line connected to an end of the first junction region.

4. The unit cell of claim 3, wherein a length of the separation region between the gate and the bit line is equal to or longer than a distance between the gate and the second junction region.

5. The unit cell of claim 1, wherein the gate is extended vertically by a surface of the active layer.

6. The unit cell of claim 5, wherein the gate comprises at least one or more of a silicon layer, a metal layer, a metal nitride layer, a metal silicide layer and a combination thereof.

7. The unit cell of claim 1, further comprising a gate insulation layer positioned on the gate.

8. The unit cell of claim 1, further comprising a storage element that includes a storage node electrically connected to an end of the second junction region.

9. The unit cell of claim 8, wherein a distance between the gate and the storage node is substantially equal to or longer than a length of the separation region between the gate and a bit line.

10. A stack type semiconductor device comprising:
an active region including an active layer and an insulating interlayer alternately stacked at least twice to form a plurality of active layers and insulating layers, each of the active layers including a first junction region and a second junction region configured to form a channel substantially parallel to a first direction;
a separation region formed in each of the active layers to separate the first junction region and the channel of each of the active layers into at least two bars;
a plurality of bit lines arranged at each of the active layers and connected to the first junction regions;
a plurality of storage elements arranged at each of the active layers and electrically connected to the second junction regions; and
a gate arranged in the separation region, extended in a stack direction of the active layers, and having an overlapped portion overlapping with respect to each of the active layers,
wherein the separation region is positioned between a common gate and the bit lines, and the gate comprises the common gate for the plurality of active layers.

11. The stack type semiconductor device of claim 10, wherein the separation region comprises an insulation material.

12. The stack type semiconductor device of claim 10, wherein a length of the separation region between the gate and the bit lines is longer than a distance between the gate and the second junction region.

13. The stack type semiconductor device of claim 12, wherein the separation region is positioned between the gate and the second junction region.

14. The stack type semiconductor device of claim 10, wherein a distance between the gate and the storage elements is substantially equal to or longer than a length of the separation region between the gate and the bit lines.

15. The stack type semiconductor device of claim 10, further comprising a gate insulation layer positioned on the gate.

16. The stack type semiconductor device of claim 15, wherein the gate is spaced apart from the second junction region by a thickness of the gate insulation layer.

17. The stack type semiconductor device of claim 10, wherein the gate comprises at least two conductive materials having different work functions.

18. The stack type semiconductor device of claim 10, wherein each of the storage elements comprises:
a plurality of storage electrodes electrically connected to the second junction regions;
a dielectric layer formed on the storage electrodes; and
a plate electrode formed on the dielectric layer and overlapped with the storage electrodes.

19-21. (canceled)

22. A unit cell for a three-dimensional semiconductor device comprising:
an active layer including a first junction region, a second junction region and a channel between the first junction region and the second junction region;
a separation region formed in the active layer to separate the first junction region and the channel into at least two portions; and
a gate arranged in the separation region, extending vertically beyond the separation region for connection to other active layers above the active layer.
